(19) United States
(12) Patent Application Publication
(10) Pub. No.: US 2008/0291073 A1
(43) Pub. Date: Nov. 27, 2008

(54) PARALLEL-TYPE A/D CONVERTER

(75) Inventor: Shigeyasu Iwata, Hamura-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Minato-ku (JP)

(21) Appl. No.: 11/938,165

(22) Filed: Nov. 9, 2007

(30) Foreign Application Priority Data
Nov. 24, 2006 (JP) 2006-317425

(51) Int. Cl. H03M 1/36

(52) U.S. Cl. 341/159

(57) ABSTRACT

According to one embodiment, a parallel-type A/D converter includes a reference voltage generating circuit which generates a plurality of reference voltages, a plurality of preamplifier circuits which amplify a potential difference between each of the reference voltages and an analog input voltage, a plurality of comparator circuits which compare sizes of the reference voltages and the analog input voltage for which a potential difference is amplified by each of the preamplifier circuits, an encoder circuit which converts a comparison result by the plurality of comparator circuits into a binary code, and a control circuit which controls gains of the plurality of preamplifier circuits and direct current offset voltages of the plurality of comparator circuits.

### CROSS-REFERENCE TO RELATED APPLICATIONS

This application is based upon and claims the benefit of priority from Japanese Patent Application No. 2006-317425, filed Nov. 24, 2006, the entire contents of which are incorporated herein by reference.

### BACKGROUND

1. Field

One embodiment of the invention relates to a parallel-type A/D converter which takes in an analog input voltage and converts the analog input voltage into a binary code.

2. Description of the Related Art

In a conventional document (Japanese Patent Application Publication (KOKAI) No. 2003-188726), there is shown an example of a parallel-type A/D converter which takes in an analog input voltage and converts the analog input voltage into a binary code. This parallel-type A/D converter is constructed including a plurality of comparator circuits connected in parallel and an encoder provided in a subsequent stage of the comparator circuits, and the encoder converts a comparison result by the comparator circuits into a binary code.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary circuit diagram of a parallel-type A/D converter according to an embodiment of the invention;

FIG. 2 is an exemplary circuit diagram of each of comparator circuits in the embodiment;

FIG. 3 is an exemplary circuit diagram of each of comparator elements in the embodiment;

FIG. 4 is an exemplary correspondence table showing output signals of NAND circuits and an AND circuit in the embodiment;

FIG. 5 is an exemplary timing chart in the case where one of the comparator elements is allowed to operate in the embodiment;

FIG. 6 is an exemplary timing chart in the case where N² number of comparator elements are allowed to operate in the embodiment;

FIG. 7 is an exemplary list showing changes of a plurality of parameters when the A/D converter is controlled in the embodiment;

FIG. 8 is an exemplary graph showing a relationship between a sampling frequency and a gain in the embodiment;

FIG. 9 is an exemplary graph showing a relationship between a sampling frequency and power consumption in the embodiment; and

FIG. 10 is an exemplary circuit diagram of a parallel-type A/D converter according to a modification example in the embodiment.

### DETAILED DESCRIPTION

Various embodiments according to the invention will be described hereinafter with reference to the accompanying drawings. In general, according to one embodiment of the invention, a parallel-type A/D converter includes a reference voltage generating circuit which generates a plurality of reference voltages, a plurality of preamplifier circuits which amplify a potential difference between each of the reference voltages and an analog input voltage, a plurality of comparator circuits which compare sizes of the reference voltages and the analog input voltage for which a potential difference is amplified by each of the preamplifier circuits, an encoder circuit which converts a comparison result by the plurality of comparator circuits into a binary code, and a control circuit which controls gains of the plurality of preamplifier circuits and direct current offset voltages of the plurality of comparator circuits.

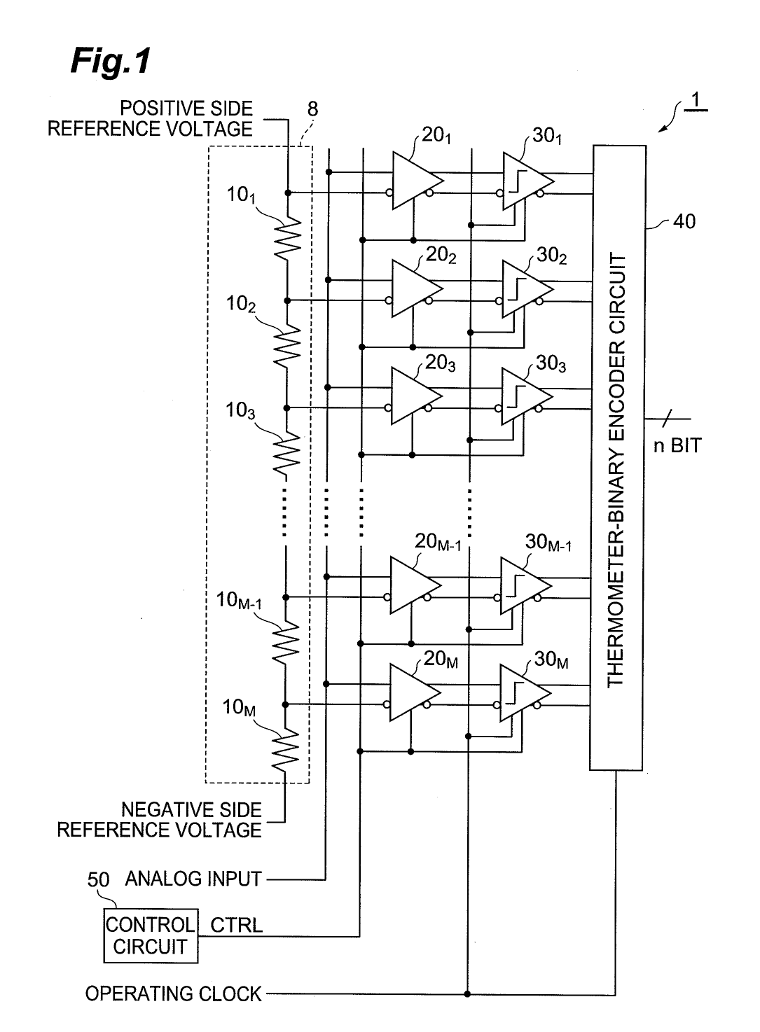

FIG. 1 shows a circuit diagram of a parallel-type A/D converter (analog-digital converter) 1 according to an embodiment of the invention. The parallel-type A/D converter 1 of this embodiment samples an analog signal read from a recording medium in a disk form according to an operating clock, and converts the analog signal into an n-bit digital signal and outputs the digital signal. Here, the storage medium in a disk form is, for example, an optical disk such as a DVD (Digital Versatile Disk), a CD (Compact Disk), or the like.

The parallel-type A/D converter 1 is constructed including a reference voltage generating circuit 8 constituted of a plurality of resistors 10₁, 10₂, 10₃, . . . , 10_{M-1}, 10_{M}, a plurality of preamplifier circuits 20₁, 20₂, 20₃, . . . , 20_{M-1}, 20_{M} connected in parallel, a plurality of comparator circuits 30₁, 30₂, 30₃, . . . , 30_{M-1}, 30_{M} connected in parallel, an encoder circuit 40, and a control circuit 50. The parallel-type A/D converter 1 is supplied externally with a positive side reference voltage, a negative side reference voltage, an analog input voltage, and an operating clock. Note that the operating clock increases in frequency according to rise of a data reading speed from the disk-form storage medium and decreases in frequency according to lowering of the data reading speed from the disk-form storage medium.

The reference voltage generating circuit 8 is constituted by connecting in series the plurality of resistors 10₁ to 10_{M} having a substantially equal resistance value, where the positive side reference voltage is applied to one end of a group of the resistors 10₁ to 10_{M} connected in series, and the negative side reference voltage is applied to the other end thereof. Voltages between two resistors 10₁ and 10₂, 10₂ and 10₃, . . . , 10_{M-1} and 10_{M} respectively are a plurality of reference voltages at constant voltage intervals between the negative side reference voltage and the positive side reference voltage.

The plurality of preamplifier circuits 20₁ to 20_{M} are provided in the same number as the resistors 10₁ to 10_{M} (which may not be the same in another embodiment), where one of the preamplifier circuits 20₁ to 20_{M} corresponds to one of the resistors 10₁ to 10_{M}. Each of the preamplifier circuits 20₁ to 20_{M} takes in a reference voltage at an upper end of a corresponding one of the resistors 10₁ to 10_{M} and takes in the analog input voltage from the outside, and then amplifies and outputs a difference between the reference voltage and the analog input voltage with a predetermined gain. Also, each of the preamplifier circuits 20₁ to 20_{M} internally includes a circuit for adjusting a band and a gain according to a control signal CTRL inputted externally. Since one common control signal is inputted to all the preamplifier circuits 20₁ to 20_{M}, gains of all the preamplifier circuits 20₁ to 20_{M} are equal to each other. Each of the preamplifier circuits 20₁ to 20_{M} is configured to sample the analog input voltage and perform the above-described processing of amplifying a potential difference. Note that the preamplifier circuits 20₁ to 20_{M} alleviate a requirement for DC offset voltages of the comparator circuits 30₁ to 30_{M} by their gains, and the preamplifier circuits 20₁ to 20_{M} also contribute largely to reduction of a kickback noise, and hence are important circuit elements.

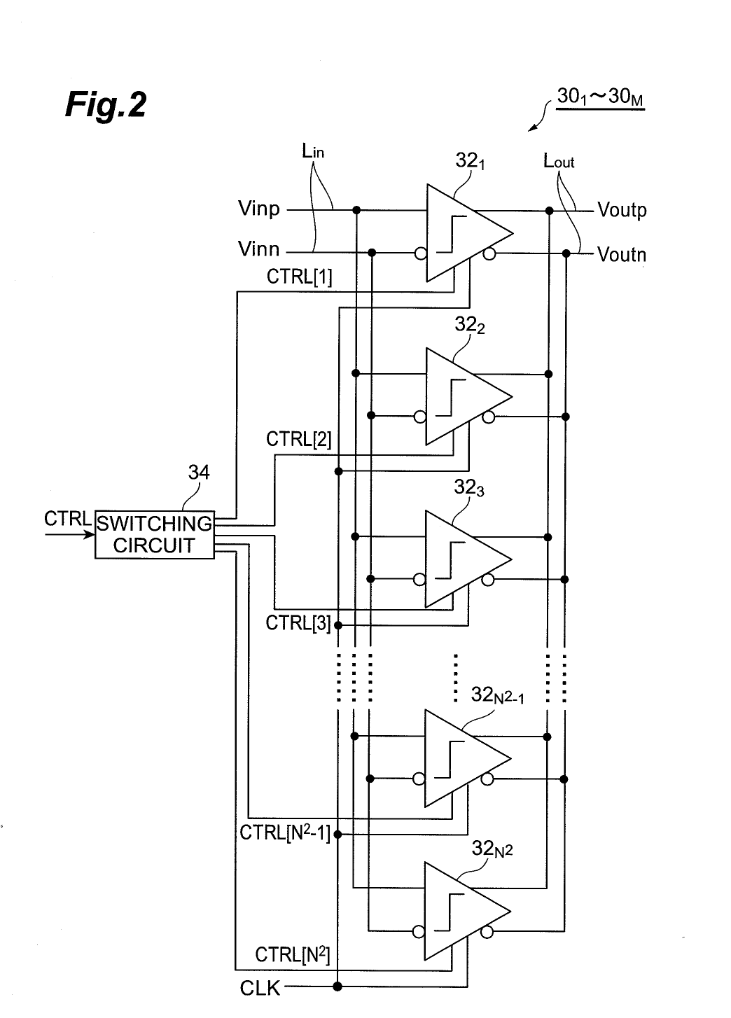

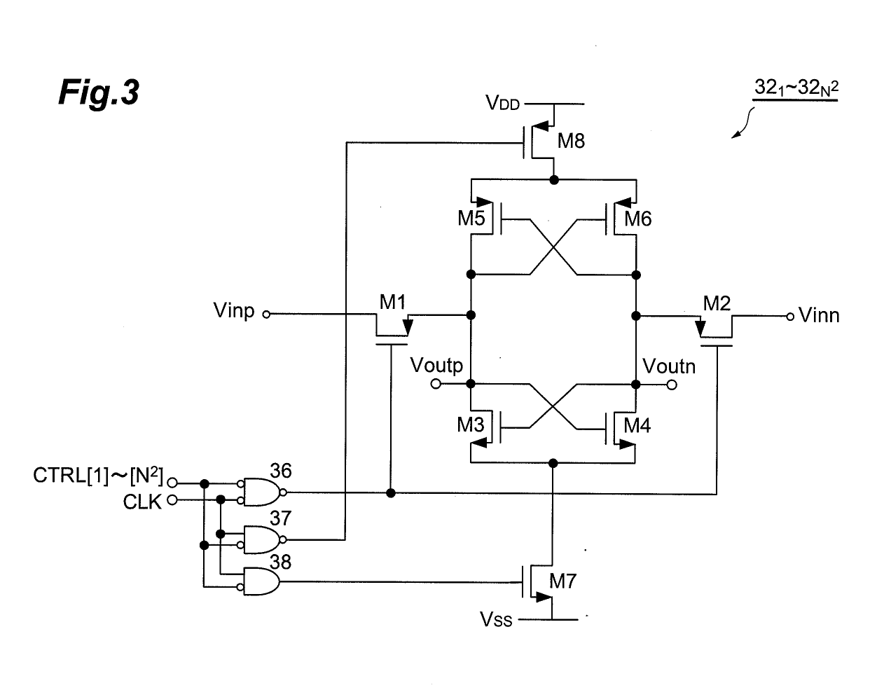

The plurality of comparator circuits 30₁ to 30_{M} are provided in the same number as the resistors 10₁ to 10_{M} and the preamplifier circuits 20₁ to 20_{M} (which may not be the same in another embodiment), where one of the comparator circuits 30₁ to 30_{M} corresponds to one of the resistors 10₁ to 10_{M} and one of the preamplifier circuits 20₁ to 20_{M}. Each of the comparator circuits 30₁ to 30_{M} takes in the potential difference amplified by corresponding one of the preamplifier circuits 20₁ to 20_{M}, compares sizes of the reference voltage and the analog input voltage based on the potential difference, and amplifies a comparison result thereof to a logic level. Each of the preamplifier circuits 10₁ to 10_{M} internally includes a circuit for adjusting a DC (direct current) offset voltage according to the control signal CTRL inputted externally. Since one common control signal is inputted to all the comparator circuits 30₁ to 30_{M}, dispersion of the DC offset voltages in all the comparator circuits 30₁ to 30_{M} are statistically equal. Each of the comparator circuits 30₁ to 30_{M} is configured to perform the above-described processing of comparing a potential difference every time the operating clock supplied externally is taken in. Note that details of each of the comparator circuits 30₁ to 30_{M} will be described later with reference to FIG. 2 and FIG. 3.

The encoder circuit 40 takes in comparison outputs of all the comparator circuits 30₁ to 30_{M}, generates an n-bit binary code based on all the comparison outputs, and outputs the binary code. Here, the binary code generated by the encoder circuit 40 represents a voltage value of the analog input voltage. The encoder circuit 40 is configured to perform the above-described processing of generating a binary code every time the operating clock supplied externally is taken in. Incidentally, as the analog input voltage increases, the comparison outputs from the comparator circuits 30₁ to 30_{M} change from 0 (zero) to 1 from a lower side one of the comparator circuits 30₁ to 30_{M}, and behave like graduations on a thermometer. After such a behavior, the encoder circuit 40 is called a “thermometer encoder”.

The control circuit 50 generates the control signal CTRL and supplies the control signal CTRL to the plurality of preamplifier circuits 20₁ to 20_{M} and the plurality of comparator circuits 30₁ to 30_{M}. This control signal CTRL is a signal for controlling gains of the plurality of preamplifier circuits 20₁ to 20_{M} and also is a signal for controlling the DC offset voltages of the plurality of comparator circuits 30₁ to 30_{M}. Note that in this embodiment the control circuit 50 supplies one common control signal CTRL to the plurality of preamplifier circuits 20₁ to 20_{M} and the plurality of comparator circuits 30₁ to 30_{M} but in another embodiment, the control circuit 50 can also be configured to supply one control signal CTRL to the plurality of preamplifier circuits 20₁ to 20_{M}, and supply another control signal CTRL to the plurality of comparator circuits 30₁ to 30_{M}.

FIG. 2 shows a circuit diagram of each of the comparator circuits 30₁ to 30_{M}, which is a part of the above-described parallel-type A/D converter 1. The comparator circuits 30₁ to 30_{M} each include a large number of comparator elements 32₁, 32₂, 32₃, . . . , 32_{N2-1}, 32_{N2} connected in parallel, and a switching circuit 34 which sets each of the comparator elements 32₁ to 32_{N2} to either an operation state or a non-operation state. The plurality of comparator elements 31₁ to 32_{N} are connected in parallel between input signal lines Lᵢₙ and output signal lines Lₒᵤₜ. Also, each of the plurality of comparator elements 32₁ to 32_{N2} is connected to the switching circuit 34. Note that in this embodiment, the number of comparator elements is the square of an integer N for the sake of simplicity in explanation, but the number of comparator elements may be any integer other than the square of an integer.

Each of the comparator elements 32₁ to 32_{N2} takes in via the two input signal lines Lᵢₙ an analog input voltage Vᵢₙₚ (hereinafter referred to as input potential Vᵢₙₚ) after a potential difference thereof is amplified by the preamplifier circuits 20₁ to 20_{M} and a reference voltage Vᵢₙₙ (hereinafter referred to as input potential Vᵢₙₙ) after a potential difference thereof is amplified by the preamplifier circuits 20₁ to 20_{M}, and compares sizes of the two input potentials Vᵢₙₚ, Vᵢₙₙ. Then, each of the comparator elements 32₁ to 32_{N2} outputs a comparison result of the two input potentials Vᵢₙₚ, Vᵢₙₙ as two output potentials Vₒᵤₜₚ, Vₒᵤₜₙ via the two output signal lines Lₒᵤₜ. Specifically, when the input potential Vᵢₙₚ is larger than the input potential Vᵢₙₙ, a logic high potential (in other words, a power supply potential V_{DD} or 1) is outputted as the output potential Vₒᵤₜₚ and a logic low potential (in other words, a ground potential V_{SS} or 0) is outputted as the output potential Vₒᵤₜₙ. On the other hand, when the input potential Vᵢₙₚ is smaller than the input potential Vᵢₙₙ, the logic low potential is outputted as the output potential Vₒᵤₜₚ and the logic high potential is outputted as the output potential Vₒᵤₜₙ.

The switching circuit 34 is a means to switch the number of comparator elements 32₁ to 32_{N2} which are set to the operation state. Specifically, the switching circuit 34 is connected to each of the comparator elements 32₁ to 32_{N2}, and outputs control signals CTRL [1] to CTRL [N²] to the comparator elements 32₁ to 32_{N2}, respectively. The control signals CTRL [1] to CTRL [N²] are signals for setting the comparator elements 32₁ to 32_{N2} to either the operation state or the non-operation state. The comparator elements 32₁ to 32_{N2} are set to turn to the operation state when the control signals CTRL [1] to CTRL [N²] are 0 (zero), and the comparator elements 32₁ to 32_{N2} are set to turn to the non-operation state when the control signals CTRL [1] to CTRL [N²] are 1. Note that the comparator elements 32₁ to 32_{N2} may be set to turn to the operation state when the control signals CTRL [1] to CTRL [N²] are 1, and the comparator elements 32 to 32_{N2} may be set to turn to the non-operation state when the control signals CTRL [1] to CTRL [N²] are 0 (zero).

The switching circuit 34 takes in the control signal CTRL from the control circuit 50, and determines the number of comparator elements 32₁ to 32_{N2} to be set to the operation state based on this control signal CTRL. Specifically, the switching circuit 34 determines, based on the control signal CTRL, which of 0 (zero) or 1 the respective control signals CTRL [1] to CTRL [N²] outputted to the respective comparator elements 32₁ to 32_{N2} should be set to. Such a control signal CTRL is a signal to instruct comparison accuracy (in other words, DC offset voltage) required for the comparator circuits 30₁ to 30_{M}. Note that the switching circuit 34 may be realized using a dedicated circuit performing processing of outputting the control signals CTRL [1] to CTRL [N²].

As described above, when the comparator circuits 30₁ to 30_{M} are constructed by connecting the plurality of comparator elements 32₁ to 32_{N2} in parallel, the comparison accuracy of the comparator circuits 30₁ to 30_{M} can be improved. Specifically, the comparison accuracy of the comparator circuits 30₁ to 30_{M} is limited by the DC offset voltages inherent in the comparator elements 32₁ to 32_{N2}, but a DC offset voltage V_{OS}_{_{—}}_{N2} of the group of the comparator elements 32₁ to 32_{N2} connected in parallel corresponds to 1/N of the DC offset voltage V_{Os}_{_{—}}₁ of one comparator element. Thus, by constructing the comparator circuits 30₁ to 30_{M} by connecting the plurality of comparator elements 32₁ to 32_{N2} in parallel, the comparison accuracy of the comparator circuits 30₁ to 30_{M} can be improved.

Since the respective DC offset voltages of the comparator elements disperse randomly to a positive side and a negative side, the larger the number of comparator elements 32₁ to 32_{N2} set to the operation state is increased, the more the respective DC offsets of the comparator elements 32₁ to 32_{N2} cancel out each other and the smaller the DC offset voltage of the comparator circuits 30₁ to 30_{M} as the whole becomes. On the other hand, the smaller the number of comparator elements 32₁ to 32_{N2} set to the operation state is decreased, the larger the DC offset voltage of the comparator circuits 30₁ to 30_{M} as the whole becomes. Specifically, in the comparator circuits 30₁ to 30_{M} of this embodiment, the DC offset voltage V_{OS}_{_{—}}_{N2} (=V_{OS}_{_{—}}₁/N) can be adjusted as the comparator circuits 30₁ to 30_{M} as the whole, and the comparison accuracy by the comparator circuits 30₁ to 30_{M} can be adjusted.

FIG. 3 shows a circuit diagram of each of the comparator elements 32₁ to 32_{N2} which is a part of the above-described comparator circuits 30₁ to 30_{M}. In the comparator elements 32₁ to 32_{N2}, a drain of a transistor M3 and a drain of a transistor M5 are connected with each other, and the transistors M3 and M5 form an inverter. Similarly, a drain of a transistor M4 and a drain of a transistor M6 are connected with each other, and the transistors M4 and M6 form another inverter. Note that in this embodiment, the transistors M3 and M4 are N-channel type transistors, and the transistors M5 and M6 are P-channel type transistors.

The two inverters are connected by cross-coupling. Specifically, a gate of the transistor M3 and a drain of the transistor M4 are connected with each other, and a gate of the transistor M4 and the drain of the transistor M3 are connected with each other. A gate of the transistor M5 and the drain of the transistor M6 are connected with each other, and a gate of the transistor M6 and the drain of the transistor M5 are connected with each other.

A source of the transistor M3 and a source of the transistor M4 are connected with each other, and a source of the transistor M5 and a source of the transistor M6 are connected with each other. Here, the transistors M3 and M4 function as an N-channel differential amplifier, and the transistors M5 and M6 function as a P-channel differential amplifier. A circuit formed by the transistors M3 to M6 is a circuit body performing an operation of comparing the input potentials Vᵢₙₚ, Vᵢₙₙ.

The drain of the transistor M3 and the drain of the transistor M5 are connected to an input end for inputting the input potential Vᵢₙₚ. The drain of the transistor M4 and the drain of the transistor M6 are connected to an input end for inputting the input potential Vᵢₙₙ. Also, the drain of the transistor M3 and the drain of the transistor M5 are connected to an output end for outputting the output potential Vₒᵤₜₚ. The drain of the transistor M4 and the drain of the transistor M6 are connected to an output end for outputting the output potential Vₒᵤₜₙ.

The output potentials Vₒᵤₜₚ, Vₒᵤₜₙ outputted from the two output ends are signals indicating a result of comparing sizes of the two input potentials Vᵢₙₚ, Vᵢₙₙ. Specifically, when the input potential Vᵢₙₚ is larger than the input potential Vᵢₙₙ, the output potential Vₒᵤₜₚ is the logic high potential V_{DD}, and the output potential Vₒᵤₜₙ is the logic low potential V_{SS}. On the other hand, when the input potential Vᵢₙₚ is smaller than the input potential Vᵢₙₙ, the output potential Vₒᵤₜₚ is the logic low potential V_{SS} and the output potential Vₒᵤₜₙ is the logic high potential V_{DD}.

A transistor M8 is a feeding switch disposed between the sources of the transistor M5 and the transistor M6 and the logic high potential V_{DD}, and turns to a connected state when 0 (zero) is applied to a gate thereof to thereby supply the logic high potential V_{DD} to the circuit body M3 to M6, and turns to a non-connected state when 1 is applied to a gate thereof to thereby disconnect the circuit body M3 to M6 from the logic high potential V_{DD}. Also, a transistor M7 is a grounding switch disposed between the sources of the transistors M3 and the transistor M4 and the logic low potential V_{SS}, and turns to a connected state when 1 is applied to a gate thereof to thereby ground the circuit body M3 to M6, and turns to a non-connected state when 0 (zero) is applied to a gate thereof to thereby disconnect the circuit body M3 to M6 from the logic low potential V_{SS}. Note that in this embodiment, the transistor M7 is an N-channel type transistor, and the transistor M8 is a P-channel type transistor.

The transistor M1 is an input switch disposed between the input end to which the input potential Vᵢₙₚ is inputted and the drains of the transistors M3 and M5, and turns to a connected state when 0 (zero) is applied to a gate thereof to thereby supply the input potential Vᵢₙₚ to the circuit body M3 to M6, and turns to a non-connected state when 1 is applied to a gate thereof to thereby disconnect the input end for inputting the input potential Vᵢₙₙ from the circuit body M3 to M6. Also, the transistor M2 is an input switch disposed between the input end to which the input potential Vᵢₙₙ is inputted and the drains of the transistors M4 and M6, and turns to a connected state when 0 is applied to a gate thereof to thereby supply the input potential Vᵢₙₙ to the circuit body M3 to M6, and disconnects the input end for inputting the input potential Vᵢₙₙ from the circuit body M3 to M6 when 1 is applied to a gate thereof. Note that in this embodiment, the transistors M1 and M2 are P-channel type transistors.

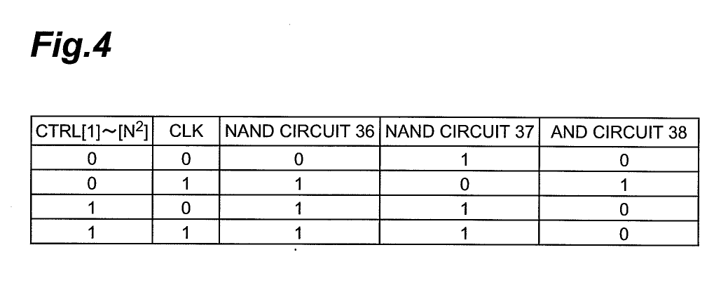

A NAND circuit 36 takes in the control signals CTRL [1] to CTRL [N²] and a clock CLK and outputs either 1 or 0 (zero) to the gates of the transistors M1 and M2 so as to drive the transistors M1 and M2. Also, a NAND circuit 37 takes in the control signals CTRL [1] to CTRL [N²] and the clock signal CLK and outputs either 1 or 0 (zero) to the gate of the transistor M8 so as to drive the transistor M8. Also, an AND circuit 38 takes in the control signals CTRL [1] to CTRL [N²] and the clock signal CLK to output either 1 or 0 (zero) to the gate of the transistor M7 so as to drive the transistor M7. A correspondence table of output signals of the two NAND circuits 36, 37 and the AND circuit 38 corresponding to the control signals CTRL [1] to CTRL [N²] and the clock signal CLK is shown in FIG. 4. Note that each of the NAND circuit 36, the NAND circuit 37, and the AND circuit 38 corresponds to a switch setting circuit.

Next, the operation of the above-described comparator elements 32₁ to 32_{N2} will be explained. When the control signals CTRL [1] to CTRL [N²] are 0 (zero), the comparator elements 32₁ to 32_{N2} are set to the operation state. Now, when the clock signal CLK is 0 (zero), the two transistors M1 and M2 for taking in the two input potentials Vᵢₙₚ, Vᵢₙₙ into the circuit body M3 to M6 turn to connected states, and hence the two input potentials Vᵢₙₚ, Vᵢₙₙ are supplied to the circuit body M3 to M6. On the other hand, the two transistors M7 and M8 for connecting to the logic high potential V_{DD} and the logic low potential V_{SS} turn to non-connected states, and hence the logic high potential V_{DD} and the logic low potential V_{SS} are not supplied to the circuit body M3 to M6, resulting in that the comparison of the two input potentials Vᵢₙₚ, Vᵢₙₙ is not performed.

When the clock signal CLK changes from 0 (zero) to 1 in the above-described state, the two transistors M1 and M2 for taking the two input potentials Vᵢₙₚ, Vᵢₙₙ into the circuit body M3 to M6 change from the connected states to non-connected states, and hence the input ends of the two input potentials Vᵢₙₚ, Vᵢₙₙ are disconnected from the circuit body M3 to M6. On the other hand, the two transistors M7 and M8 for connecting to the logic high potential V_{DD} and the logic low potential V_{SS} change from the non-connected states to connected states, and hence the difference between the two input potentials Vᵢₙₚ, Vᵢₙₙ already supplied to the circuit body M3 to M6 is amplified, and a comparison result is outputted as the output potentials Vₒᵤₜₚ, Vₒᵤₜₙ from the output ends.

Here, the transistors M3 to M6 function as a latch. Specifically, the transistors M3 to M6 keep retaining a state that one of the output potentials Vₒᵤₜₚ, Vₒᵤₜₙ is the logic high potential V_{DD}, and the other one of them is the logic low potential V_{SS}. Then, when the clock signal CLK returns again from 1 to 0 (zero), the two transistors M7 and M8 for connecting to the logic high potential V_{DD} and the logic low potential V_{SS} turn to non-connected states, and hence the retaining of the output potentials Vₒᵤₜₚ, Vₒᵤₜₙ finishes. Note that when the clock signal CLK returns again from 1 to 0 (zero), the two transistors M1 and M2 for taking the two input potentials Vᵢₙₚ, Vᵢₙₙ into the circuit body M3 to M6 turn to connected states, and hence the two input potentials Vᵢₙₚ, Vᵢₙₙ are outputted as they are as the output potentials Vₒᵤₜₚ, Vₒᵤₜₙ from the output ends.

When the control signals CTRL [1] to CTRL [N²] are 1, the comparator elements 32₁ to 32_{N2} are set to the non-operation state. Now, when the clock signal CLK is either 0 (zero) or 1, the two transistors M1 and M2 for taking the two input potentials Vᵢₙₚ, Vᵢₙₙ into the circuit body M3 to M6 turn to non-connected states, and hence the two input potentials Vᵢₙₚ, Vᵢₙₙ are not supplied to the circuit body M3 to M6. Also, the two transistors M7 and M8 for connecting to the logic high potential V_{DD} and the logic low potential V_{SS} both turn to non-connected states, and hence the circuit body M3 to M6 turns to a disconnected state from the logic high potential V_{DD} and the logic low potential V_{SS}.

In the above-described comparator circuits 30₁ to 30_{M}, the switching circuit 34 sets the comparator elements 32₁ to 32_{N2} to the non-operation state, and the NAND circuit 37 sets the transistor M8 to a non-connected state, to thereby electrically disconnect the circuit body M3 to M6 from the logic high potential V_{DD}. If the circuit body M3 to M6 were connected to the logic high potential V_{DD} when the comparator elements 32₁ to 32_{N2} are set to the non-operation state, the differential amplifier M5, M6 connected to the logic high potential V_{DD} is allowed to operate and causes the time constant of the entire circuit to change, and thus the comparison accuracy of the comparator circuits 30₁ to 30_{M} is impaired. In this aspect, as in this embodiment, when the comparator elements 32₁ to 32_{N2} are set to the non-operation state, the circuit body M3 to M6 of each of the comparator elements 32₁ to 32_{N2} is electrically disconnected from the logic high potential V_{DD} with the transistor M8 being a high impedance, which results in that the comparator elements 32₁ to 32_{N2} which are set to the non-operation state do not affect the comparison operation of the other comparator elements 32₁ to 32_{N2}, and thereby the comparison accuracy of the comparator circuits 30₁ to 30_{M} as the whole can be maintained.

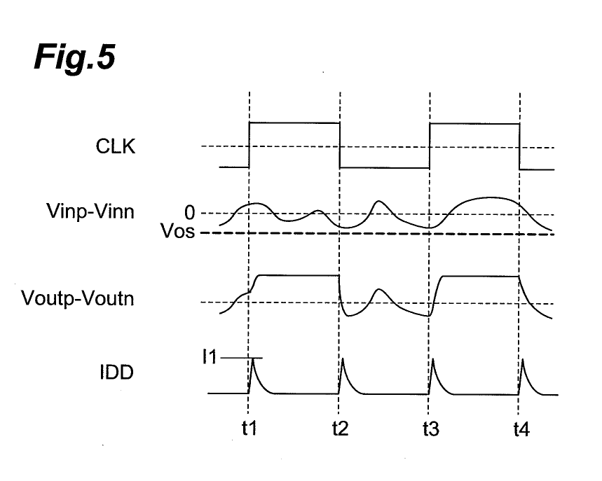

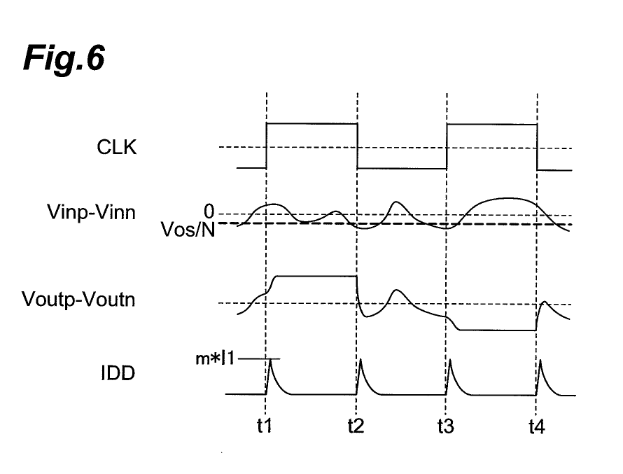

Next, with reference to FIG. 5 and FIG. 6, characteristics regarding comparison accuracy and power consumption of the above-described comparator circuits 30₁ to 30_{M} will be explained. FIG. 5 is a timing chart in the case where an equivalent input DC offset voltage of one of the comparator circuits 30₁ to 30_{M} is Vos, in other words, only one of the comparator elements 32₁ to 32_{N2} is allowed to operate by the control signal CTRL. FIG. 6 is a timing chart in the case where an equivalent input DC offset voltage of one of the comparator circuits 30₁ to 30_{M} is Vos/N, in other words, N² number of comparator elements 32₁ to 32_{N2} are allowed to operate by the control signal CTRL.

In the timing chart of FIG. 5, between time t1 and time t2, according to the difference Vᵢₙₚ−Vᵢₙₙ between the input potentials being 0 (zero) or larger, the difference Vₒᵤₜₚ−Vₒᵤₜₙ between the output potentials is V_{DD}−V_{SS}, and the comparator circuits 30₁ to 30_{M} make a judgment normally. Between time t3 and time t4, although the difference Vᵢₙₚ−Vᵢₙₙ between the input potentials is 0 (zero) or smaller, the difference Vₒᵤₜₚ−Vₒᵤₜₙ between the output potentials is V_{DD}−V_{SS} since the absolute value of the equivalent input offset voltage V_{OS} is large, and the comparator circuits 30₁ to 30_{M} make a false judgment. Also, since the number of comparator elements 32₁ to 32_{N2} in an operation state is small, a consumed current IDD is small. Thus, when the equivalent input DC offset voltages of the comparator circuits 30₁ to 30_{M} are large, there is a characteristic that although the comparison accuracy is poor, the power consumption is reduced.

On the other hand, in the timing chart of FIG. 6, between time t1 and time t2, according to the difference Vᵢₙₚ−Vᵢₙₙ between the input potentials being 0 (zero) or larger, the difference Vₒᵤₜₚ−Vₒᵤₜₙ between the output potentials is V_{DD}−V_{SS}, and the comparator circuits 30₁ to 30_{M} make a judgment normally. Also, between time t3 and time t4, according to the difference Vᵢₙₚ−Vᵢₙₙ between the input potentials being 0 or larger since the absolute value of the equivalent input offset voltage V_{OS}/N is small, difference Vₒᵤₜₚ−Vₒᵤₜₙ between the output potentials can be −V_{DD}+V_{SS}, thereby preventing a false judgment due to the DC offset voltage. However, since the number of comparator elements 32₁ to 32_{N2} in an operation state is large, the consumed current IDD is large. Thus, when the equivalent input DC offset voltages of the comparator circuits 30₁ to 30_{M} are small, there is a characteristic that although the comparison accuracy is excellent, the power consumption increases.

As explained above, the DC offset voltage due to dispersion in elements of the comparator circuits 30₁ to 30_{M} limits the comparison accuracy thereof, and therefore is a main cause of limiting conversion accuracy of the parallel-type A/D converter 1. Also, the DC offset voltage due to dispersion in elements of the preamplifier circuits 20₁ to 20_{M} is similarly a main cause of limiting the conversion accuracy of the parallel-type A/D converter 1. The equivalent input DC offset voltage Vos_{ADC} of the entire parallel-type A/D converter 1 is represented by the following equation (1) based on the equivalent input DC offset voltages Vos_{CMP} of the comparator circuits 30₁ to 30_{M} and the equivalent input DC offset voltages Vos_{PREAMP} and the gains Av_{PREAMP} of the preamplifier circuits 20₁ to 20_{M}.

$${Vos}_{ADC} = \sqrt{{( {Vos}_{PREAMP} )}^{2} + {( \frac{{Vos}_{CMP}}{{Av}_{PREAMP}} )}^{2}} \qquad ( 1 )$$

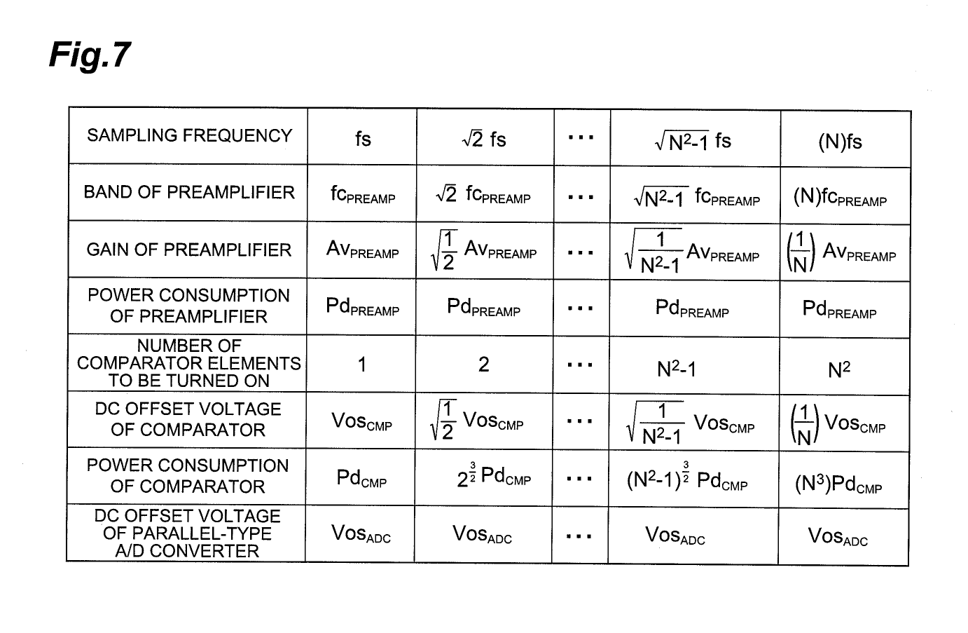

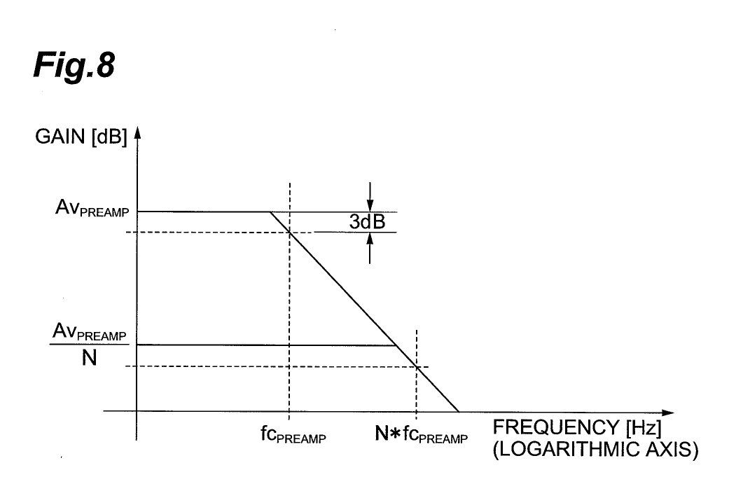

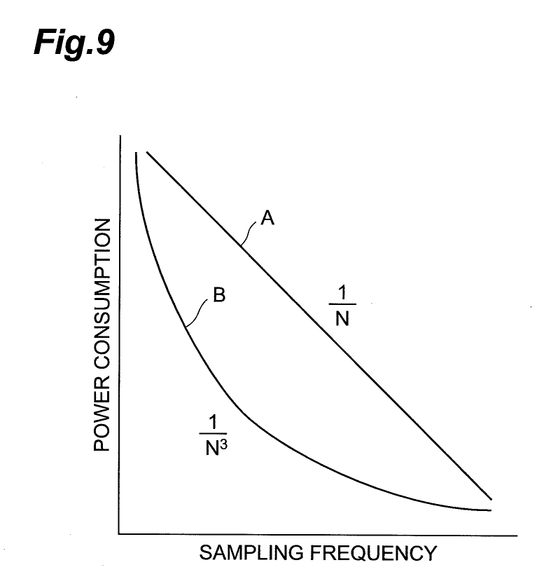

In the parallel-type A/D converter 1 of this embodiment, using the above-described characteristics of the comparator circuits 30₁ to 30_{M}, the preamplifier circuits 20₁ to 20_{M} and the comparator circuits 30₁ to 30_{M} are controlled according to a sampling frequency, while the conversion accuracy and the power consumption in the parallel-type A/D converter 1 are taken into consideration. With reference to FIG. 7, FIG. 8 and FIG. 9, a control method of the preamplifier circuits 20₁ to 20_{M} and the comparator circuits 30₁ to 30_{M} in the parallel-type A/D converter 1 of this embodiment will be explained below.

In the list of FIG. 7, there are shown (I) sampling frequencies, bands, gains, and power consumption of the preamplifier circuits 20₁ to 20_{M}, (II) the number of comparator elements 32₁ to 32_{N2} in an operation state of the comparator circuits 30₁ to 30_{M}, DC offset voltages, and power consumption of the preamplifier circuits 20₁ to 20_{M}, and (III) DC offset voltages of the parallel-type A/D converter 1. Then, there is shown how these parameters change when the preamplifier circuits 20₁ to 20_{M} and the comparator circuits 30₁ to 30_{M} are controlled.

In the parallel-type A/D converter 1, parameters such as bands and gains of the preamplifier circuits 20₁ to 20_{M}, the number of comparator elements 32₁ to 32_{N2} of the comparator circuits 30₁ to 30_{M}, and so on are determined so as to perform an optimum operation when the sampling frequency is high. For example, as shown in the rightmost row in FIG. 7, the bands of the preamplifier circuits 20₁ to 20_{M} are set to N*fc_{PREAMP} and the gains are set to Av_{PREAMP}/N so as to perform an optimum operation when the sampling frequency is N*fs. Also, the maximum number of comparator elements 32₁ to 32_{N2} is set to N and the minimum DC offset voltages of the comparator circuits 30₁ to 30_{M} are set to Vos_{CMP}/N.

When the sampling frequency changes to 1/N-fold from N*fs to fs, the control circuit 50 of the parallel-type A/D converter 1 adjusts the control signal CTRL so as to (i) control the bands of the preamplifier circuits 20₁ to 20_{M} to be 1/N-fold and the gains thereof to be N-fold, and (ii) control the number of comparator elements 32₁ to 32_{N2} in an operation state to be reduced from N² to one so that the DC offset voltages of the comparator circuits 30₁ to 30_{M} become N-fold. Reasons for adopting such a control method will be explained below.

(i) reasons for controlling the bands of the preamplifier circuits 20₁ to 20_{M} to be 1/N-fold and the gains thereof to be N-fold will be explained. In general, since a phase shift due to an insufficient band for the preamplifier circuits 20₁ to 20_{M} deteriorates a distortion characteristic of the A/D converter 1, the bands of the preamplifier circuits 20₁ to 20_{M} are needed to be sufficiently larger as compared to a Nyquist frequency of the A/D converter 1. When the sampling frequency changes to 1/N-fold, the Nyquist frequency changes to 1/N-fold, and thus a problem of deteriorating the distortion characteristic of the A/D converter 1 does not occur even when the bands of the preamplifier circuits 20₁ to 20_{M} are changed to 1/N-fold from N*fc_{PREAMP} to fc_{PREAMP}. Accordingly, control is performed so that the bands of the preamplifier circuits 20₁ to 20_{M} become 1/N-fold and the gains thereof become N-fold by adjusting the control signal CTRL, thereby alleviating a requirement for the DC offset voltages Vos_{CMP} of the comparator circuits 30₁ to 30_{M}. Note that as can be understood from a relationship between a sampling frequency and a gain shown in FIG. 8, the gain-bandwidth product of the preamplifier circuits 20₁ to 20_{M} is constant before and after adjusting the control signal CTRL. Thus, the power consumption Pd_{PREAMP} of the preamplifier circuits 20₁ to 20_{M} is constant.

(ii) reasons for controlling the DC offset voltages of the comparator circuits 30₁ to 30_{M} to be N-fold will be explained. Referring to the above equation (1) it can be understood that, when the gains of the preamplifier circuits 20₁ to 20_{M} become N-fold, the conversion accuracy of the A/D converter 1 is maintained even when the DC offset voltages of the comparator circuits 30₁ to 30_{M} change to N-fold. Accordingly, when the number of comparator elements 32₁ to 32_{N2} in an operation state is controlled to decrease from N² to one by adjusting the control signal CTRL so that the DC offset voltages of the comparator circuits 30₁ to 30_{M} become N-fold, the conversion accuracy of the A/D converter 1 does not change and is maintained constantly. At this time, the sampling frequency becomes 1/N-fold and the number of times of operations of the circuits changes to 1/N-fold, and the number of comparator elements 32₁ to 32_{N2} in an operation state becomes 1/N²-fold, and hence the power consumption Pd_{CMP} of the comparator circuits 30₁ to 30_{M} is reduced to 1/N³.

In the above-described control method, when the sampling frequency becomes low, the parallel-type A/D converter 1 can significantly reduce the power consumption to 1/N³ while keeping the conversion accuracy of the A/D converter 1 constant. For example, as shown in FIG. 9, in the case where the number of comparator elements 32₁ to 32_{N2} in an operation state is not decreased when the sampling frequency changes to 1/N-fold, the power consumption of the comparator circuits 30₁ to 30_{M} is only reduced to 1/N, and an effect of reducing the power consumption is small (straight line A). In contrast, in the case where the number of comparator elements 32₁ to 32_{N2} in an operation state is reduced to 1/N²-fold when the sampling frequency changes to 1/N-fold by the above-described control method, the power consumption of the comparator circuits 30₁ to 30_{M} is reduced to 1/N³-fold, and the effect of reducing the power consumption is quite large (curve B).

Note that in the above-described embodiment, to maintain the conversion accuracy of the A/D converter 1, when the sampling frequency changes to 1/N, the bands of the preamplifier circuits 20₁ to 20_{M} are controlled to be 1/N-fold and the gains thereof are controlled to be N-fold, and the DC offset voltages of the comparator circuits 30₁ to 30_{M} are controlled to be N-fold, by adjusting the control signal CTRL. However, the control method of the bands and gains of the preamplifier circuits 20₁ to 20_{M} and the DC offset voltages of the comparator circuits 30₁ to 30_{M} is not limited thereto as long as it is capable of reducing the power consumption in the A/D converter 1. For example, the method may be one which performs control so that the gains of the preamplifier circuits 20₁ to 20_{M} are increased and the DC offset voltages of the comparator circuits 30₁ to 30_{M} are increased according to lowering of the sampling frequency.

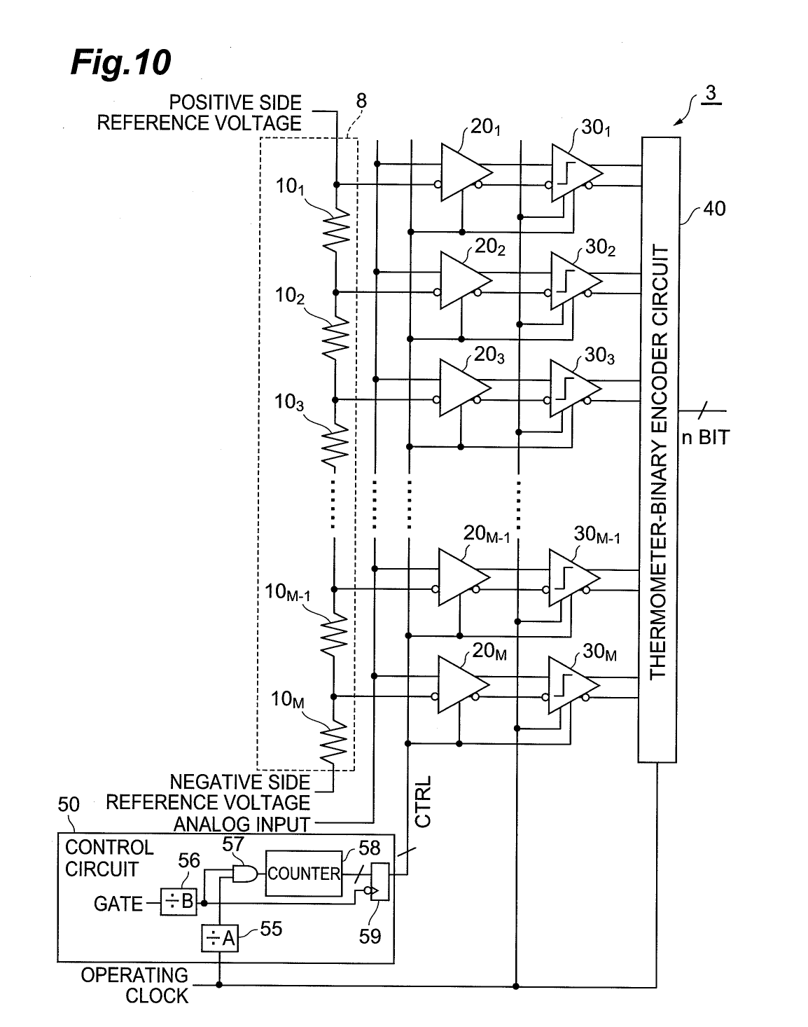

Next, a modification example of the above-described embodiment will be explained. FIG. 10 shows a circuit diagram of a parallel-type A/D converter 3 according to a modification example. In the parallel-type A/D converter 3 according to the modification example, the control circuit 50 is a frequency counter which measures and outputs the frequency of an operating clock, and includes for example a frequency dividing circuit 55 with a frequency dividing ratio A, a frequency dividing circuit 56 with a frequency dividing ratio B, an AND circuit 57, a counter 58, and a D-type flip-flop 59.

The frequency dividing circuit 55 takes in an operating clock at a constant cycle C, and generates and outputs a clock signal at a constant cycle C/A adjusted by the frequency dividing ratio A. The frequency dividing circuit 56 takes in a gate signal which is a clock signal at a constant cycle G, and generates and outputs a clock signal at a cycle G/B adjusted by the frequency dividing ratio B. The AND circuit 57 takes in output signals of the two frequency dividing circuits 55, 56, and outputs a logic high potential when the two output signals both become logic high potentials and outputs a logic low potential in other cases.

The counter 58 takes in an output signal of the AND circuit 57 and counts up the number of times that the output signal of the AND circuit 57 becomes a logic high potential within a constant time, and outputs a count value thereof. At every timing when the clock signal from the frequency dividing circuit 56 becomes a logic high potential, the D-type flip-flop 59 which is a register takes in an output signal of the count value from the counter 58 to retain the count value, and outputs the count value as the control signal CTRL to the preamplifier circuits 20₁ to 20_{M} and the comparator circuits 30₁ to 30_{M}.

The control signal CTRL outputted from the control circuit 50 is a value that is proportional to the frequency of the operating clock, and represents the frequency of the operating clock. Specifically, as the frequency of the operating clock becomes faster, the control signal CTRL becomes a larger value, and as the frequency of the operating clock becomes lower, the control signal CTRL becomes a smaller value.

With the parallel-type A/D converter 3 according to the above-described modification example, when the sampling frequencies of the preamplifier circuits 20₁ to 20_{M} become fast according to that the operating clock becomes fast, the control signal CTRL becomes a large value. Thus, the bands of the preamplifier circuits 20₁ to 20_{M} increase, and the gains thereof decrease. Also, the number of comparator elements 32₁ to 32_{N2} in an operation state increases and the DC offset voltages of the comparator circuits 30₁ to 30_{M} decrease. With such control, the parallel-type A/D converter 3 adapts to a high-speed operation state.

On the other hand, with the parallel-type A/D converter 3 according to the above-described modification example, when the sampling frequencies of the preamplifier circuits 20₁ to 20_{M} become slow according to that the operating clock becomes slow, the control signal CTRL becomes a small value. Thus, the bands of the preamplifier circuits 20₁ to 20_{M} decrease and the gains thereof increase. Also, the number of comparator elements 32₁ to 32_{N2} in a n operation state decreases and the DC offset voltages of the comparator circuits 30₁ to 30_{M} increase. With such control, the parallel-type A/D converter 3 adapts to a low-speed operation state, and the power consumption thereof is reduced significantly.

Note that the operation frequency of the counter 58 can be adjusted by changing the frequency dividing ratios A, B of the frequency dividing circuits 55, 56 appropriately. For example, when operations of the preamplifier circuits 20₁ to 20_{M} and the comparator circuits 30₁ to 30_{M} may be low speed, the frequency dividing ratios A, B are increased to make the counter 58 operate at low speed, and thereby increase in power consumption due to addition of the counter 58 can be suppressed.

Note that the parallel-type A/D converters 1, 3 of the above-described embodiment convert an analog signal read from an optical disk into a digital signal, but the parallel-type A/D converters 1, 3 may convert an analog signal read from another type of storage medium into a digital signal. Another type of storage medium is, for example, a magnetic disk such as HD (Hard Disk), FD (Floppy Disk) (registered trademark), and a magnetic optical disk such as MO (Magneto-Optical Disk). Also, the parallel-type A/D converters 1, 3 may be used for a different application other than conversion of an analog signal into a digital signal.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A parallel-type A/D converter, comprising:
a reference voltage generating circuit configured to generate a plurality of reference voltages;
a plurality of preamplifier circuits configured to amplify a potential difference between each of the reference voltages and an analog input voltage;
a plurality of comparator circuits configured to compare values of the reference voltages with the analog input voltage for which a potential difference is amplified by each of said preamplifier circuits;
an encoder circuit configured to convert a comparison result by said plurality of comparator circuits into a binary code; and
a control circuit configured to control the gains of said plurality of preamplifier circuits and to control the direct current offset voltages of said plurality of comparator circuits.

2. The parallel-type A/D converter according to claim 1, wherein said control circuit is configured to control the gains of said plurality of preamplifier circuits and to control the direct current offset voltages of said plurality of comparator circuits so as to reduce power consumption of the A/D converter based on an operating clock supplied to the A/D converter.

3. The parallel-type A/D converter according to claim 2, wherein said control circuit is configured to increase the gains of said preamplifier circuits and to increase the direct current offset voltages of said comparator circuits in response to lowering of the frequency of the operating clock supplied to the A/D converter.

4. The parallel-type A/D converter according to claim 2, wherein said control circuit is configured to make the bandwidths of said preamplifier circuits become 1/N-fold, the gains of said preamplifier circuits become N-fold, and the direct current offset voltages of said comparator circuits become N-fold in response to lowering of the frequency of the operating clock supplied to the A/D converter to 1/N.

5. The parallel-type A/D converter according to claim 2, wherein the operating clock supplied to the A/D converter is configured to increase in frequency in response to an increase of a data reading speed from a disk-form storage medium and to decrease in frequency in response to a decrease of the data reading speed from the disk-form storage medium.

6. The parallel-type A/D converter according to claim 1, wherein said control circuit is configured to generate and output at least one control signal corresponding to the frequency of the operating clock supplied to the A/D converter so as to control the gains of said plurality of preamplifier circuits and the direct current offset voltages of said plurality of comparator circuits.

7. The parallel-type A/D converter according to claim 6, wherein said control circuit comprises:
a first frequency dividing circuit configured to reduce the frequency of the operating clock and to output the clock with the reduced frequency;
a second frequency dividing circuit configured to reduce the frequency of a clock which is different from the operating clock and to output the clock with the reduced frequency;
a logical AND circuit configured to output a logic high potential when said first frequency dividing circuit and said second frequency dividing circuit both output a a counter in which a count value is configured to increase when said logical AND circuit outputs the logic high potential; and
a register configured to retain a count value from said counter and to output the count value as the at least one control signal.

8. The parallel-type A/D converter according to claim 1, wherein each of said comparator circuits comprises:
a plurality of comparator elements connected in parallel between input signal lines and output signal lines, each of said plurality of comparator elements being configured to compare input potentials on the input signal lines and to output a comparison result to the output signal lines; and
a switching circuit capable of setting each of said comparator elements to either an operation state in which comparison of the input potentials is performed or a non-operation state in which comparison of the input potentials is not performed, said switching circuit switching the number of comparator elements set to the operation state.

9. The parallel-type A/D converter according to claim 8, wherein:
each of said comparator elements comprises a circuit body configured to perform an operation of comparing input potentials on the input signal lines; and
said circuit body comprises a first P-channel type transistor, a second P-channel type transistor, a first N-channel type transistor, and a second N-channel type transistor, wherein:
a source of the first P-channel type transistor and a source of the second P-channel type transistor are connected with each other;
a drain of the first P-channel type transistor and a gate of the second P-channel type transistor are connected with each other, and a drain of the second P-channel type transistor and a gate of the first P-channel type transistor are connected with each other;
the drain of the first P-channel type transistor and a drain of the first N-channel type transistor are connected with each other, and the drain of the second P-channel type transistor and a drain of the second N-channel type transistor are connected with each other;
a first input signal line and a first output signal line are connected to the drain of the first P-channel type transistor, and a second input signal line and a second output signal line are connected to the drain of the second P-channel type transistor;
the drain of the first N-channel type transistor and a gate of the second N-channel type transistor are connected with each other, and the drain of the second N-channel type transistor and a gate of the first N-channel type transistor are connected with each other; and
a source of the first N-channel type transistor and a source of the second N-channel type transistor are connected with each other.

10. The parallel-type A/D converter according to claim 9, wherein each of said comparator elements comprises:
an input switch disposed between said circuit body and the input signal line;
a grounding switch disposed between said circuit body and the ground potential; and
a switch setting circuit configured to set, when said each comparator element is set to the operation state, said input switch to a connected state and to set said grounding switch to a non-connected state according to a clock signal of a logic high potential, and to set said input switch to a non-connected state and to set said grounding switch to a connected state according to a clock signal of a logic low potential.
